(19) United States
(12) Patent Application Publication
(10) Pub. No.: US 2013/0088681 A1
(43) Pub. Date: Apr. 11, 2013

(54) DISPLAY PANEL AND DISPLAY DEVICE

(71) Applicants: Yuhko Hisada, Osaka-shi (JP); Hironobu Sawada, Osaka-shi (JP); Junichi Morinaga, Osaka-shi (JP); Katsushige Asada, Osaka-shi (JP)

(72) Inventors: Yuhko Hisada, Osaka-shi (JP); Hironobu Sawada, Osaka-shi (JP); Junichi Morinaga, Osaka-shi (JP); Katsushige Asada, Osaka-shi (JP)

(21) Appl. No.: 13/700,445

(22) PCT Filed: May 24, 2011
(86) PCT No.: PCT/JP2011/061902

§ 371 Date: Nov. 28, 2012

(30) Foreign Application Priority Data
Jun. 28, 2010 (JP) 2010-146825

(51) Int. Cl. H01L 27/15; G02F 1/1362

(52) U.S. Cl. CPC H01L 27/153; G02F 1/136286
USPC 349/144; 257/88

(57) ABSTRACT

An object of the present invention is to provide a display panel and a display device which are able to sufficiently increase the luminance, and to suppress the occurrence of difference in response speed, transmissivity, and viewing angle characteristics, and the like for each color, and which are also able to improve the yield in the manufacturing process, and are able to be applied to various display modes, such as a CPA mode, an MVA mode, and an IPS mode. According to the present invention, there is provided a display panel in which one pixel is formed by a plurality of sub-pixels, the display panel being configured such that, when one pixel is divided into a plurality of rectangular regions, at least one of the rectangular regions includes two or more sub-pixels, such that, in each of the sub-pixels, the length of the side in parallel with the short side of the rectangular region is substantially the same, and such that, in at least one of the sub-pixels, the length of the side in parallel with the long side of the rectangular region is different.

### TECHNICAL FIELD

The present invention relates to a display panel and a display device. More particularly, the present invention relates to a display technique using multiple primary colors in a display panel, and particularly relates to a display panel and a display device which are able to exhibit display characteristics, such as high luminance, and wide color reproduction range, by means of pixels each configured by using four or more multiple primary colors, and which are able to be applied to various display modes, such as a CPA (Continuous Pinwheel Alignment) mode, a MVA (Multi-domain Vertical Alignment) mode, and an IPS (In-Plane-Switching) mode.

### BACKGROUND ART

In a display panel, one pixel is generally formed by including color units of basic three primary colors consisting of red (R), blue (B) and green (G), or by including color units of more than three colors. Panels based on various systems have been put into practical use, and many products ranging from mobile display panels to large-sized display panels have been supplied. Among the display panels, liquid crystal display panels, each of which is configured by sandwiching a liquid crystal display element between a pair of glass substrates, and the like, have features, such as thin thickness, lightweight, and low power consumption. Because of such features, liquid crystal display panels have been used for mobile applications, and applications such as various monitors and televisions, and hence have become indispensable in everyday life and business. In recent years, liquid crystal display panels have been widely adopted for such applications as electronic books, photo frames, IAs (industrial apparatuses), and PCs (personal computers). In these applications, mobile display panels, which are to be incorporated in small and medium-sized models and which have high definition and high transmittance characteristics, have been strongly required.

As for such display panel, there have been reported techniques relating to display devices (mainly TV models, and the like) in which pixel areas are changed for respective colors for improvement of white luminance and/or expansion of color reproduction range, and the like, and in which pixels, such as RGBY pixels, each having four or more multiple primary colors, are used (see, for example, Patent Literatures 1 to 5).

Further, there is disclosed a color display device in which unit pixel arrays each formed by sub-pixels of four colors are arranged in a matrix form to perform color display, and in which the areas and the number of sub-pixels for display of each color are changed while the total area of the sub-pixels of respective colors is set to be substantially the same (see, for example, Patent Literature 6).

### CITATION LIST

### Patent Literature

Patent Literature 1: WO 2007/063620
Patent Literature 2: WO 2007/088656
Patent Literature 3: JP 2008-015070 A
Patent Literature 4: WO 2008/153003
Patent Literature 5: WO 2007/013210
Patent Literature 6: JP 2008-96549 A

### SUMMARY OF INVENTION

### Technical Problem

In the conventionally designed display panels described in Patent Literatures 1 to 5 described above, a panel, which satisfies the requirements for both high luminance and wide color reproduction range, can be obtained in such a manner that a liquid crystal panel (FIG. 19) for three colors of RGB, and the like, is made to correspond to multiple primary colors, such as four primary colors of RGBW and four primary colors of RGBY (FIG. 20), that the aperture ratio (display area) is changed for each of the colors (FIG. 21), and that the display area of each of the colors (R, B) usually having a low luminosity factor is increased so as to avoid a decrease in the luminance of each of the colors (R, B) as much as possible (to make the decrease in the luminance hardly visually recognized) and so as to improve the white luminance. Note that FIG. 21 exemplifies a display panel in which the difference between the display areas is set as 1.5:1. However, in the conventionally designed display panels, the size of the sub-pixel is changed for each color, and hence, for example, in the display panel in which sub-pixels are arranged in a stripe shape, the short side of the sub-pixel is reduced. Especially in a high definition panel and a panel made to correspond to multiple primary colors, the size of the sub-pixel per color is reduced, and the size of the small sub-pixel (especially the length of the short side) is further reduced. As a result, the pattern density of the small sub-pixels is increased, so that the yield is lowered and the aperture ratio is reduced. Thereby, the merit of the display panel using multiple primary colors is hardly obtained. Further, the size of the sub-pixel electrode of the sub-pixel is different for each color, and thereby the response and viewing angle characteristics are made different for each color.

Further, in the color display device described in Patent Literature 6 described above, the total area of the sub-pixels of respective colors is set to be substantially the same. In such display device which is not made to correspond to display using three colors of RGB but is made to correspond to display using four colors of RGBW, or the like, the white luminance can be made higher than that of the display device which is made to correspond to display using three colors of RGB. However, the total area of the sub-pixels of respective colors is set to be substantially the same, and hence the reduction in the luminance in the monochromatic display cannot be avoided.

In the case where the size of the sub-pixel is reduced to increase the precision of the panel, it is especially effective to use a CPA (Continuous Pinwheel Alignment) mode, for example, in a liquid crystal display panel. However, when the size of the sub-pixel is reduced, the ratio of the non-transmissive portion is increased, in which portion wirings and TFTs required for driving the sub-pixel, and alignment regulation means (domain division means) are arranged. Thereby, in the display panel made to correspond to four primary colors, or the like, the influence of the reduction in the aperture ratio is increased, so that the merit of the display panel using multiple primary colors is hardly obtained. Further, when the area of the sub-pixel electrode is changed in order to change the display area of the sub-pixel, the distance between the edge of the sub-pixel electrode and the alignment regulation means is changed for each color in the conventional design. As a result, the characteristics, such as the response speed, the transmissivity, and the viewing angle, become different depending on colors, and the difference in these characteristics becomes a cause of coloring and oblique coloring. Further, as for the display technique using multiple primary colors, various display modes, such as a MVA mode and an IPS mode, also have problems similar to the problems described above.

The present invention has been made in view of the above described circumstances. An object of the present invention is to provide a display panel and a display device which are able to sufficiently increase the luminance and to suppress the occurrence of difference in the response speed, transmissivity, and viewing angle characteristics for each color, and which are also able to improve the yield in the manufacturing process, and are able to be applied to various display modes, such as a CPA mode, an MVA mode, and an IPS mode.

### Solution to Problem

The present inventors applied, to various display modes, such as a CPA mode, an MVA mode, and an IPS mode, a display technique using multiple primary colors, especially a display technique in which each of pixels is formed by four or more multiple primary colors to expand the color reproduction range. At this time, the present inventors paid attention to that the above-described problems are caused when the decrease in the luminance in monochromatic display is avoided as much as possible in the conventional art, and that the problems are caused by the fact that the length of the short side of the sub-pixel is made different for each color, and thereby the length of the short side of the small sub-pixel is made very small. As a result, the present inventors found out that, in the configuration based on the conventional art, since the influence of the reduction in the aperture ratio is large in the display panel made to correspond to multiple primary colors, the luminance is reduced, so that the advantage of the display panel using multiple primary colors is not sufficiently obtained, and also a high yield (high productivity of product) is not sufficiently obtained. Further, the present inventors came up with an idea that the above-described problems can be effectively solved by a form in which a rectangular region is specified in one pixel formed by a plurality of sub-pixels, in which, in the sub-pixels, the length of the side in parallel with the short side of the rectangular region is substantially the same, and in which, in at least one of the sub-pixels, the length of the side in parallel with the long side of the rectangular region is different, and reached the present invention.

That is, according to the present invention, there is provide a display panel in which one pixel is formed by a plurality of sub-pixels, the display panel being featured in that, when a region including one pixel is divided into a plurality of rectangular regions, at least one of the rectangular regions includes two or more sub-pixels, in that, in each of the sub-pixels, the length of the side in parallel with the short side of the rectangular region is substantially the same, and in that, in at least one of the sub-pixels, the length of the side in parallel with the long side of the rectangular region is different. When the yield in a manufacturing process is taken into consideration, a certain amount of distance is required between different patterns. In the case where pixel components each having the same area are arranged in a sub-pixel, when a side of a sub-pixel electrode is short as shown in FIG. 24, the pixel component is made to extend in the long side direction, and hence the aperture ratio cannot be sufficiently increased. However, when the short side of the sub-pixel electrode can be made longer, the length of the other side of the pixel component is suppressed to be short as shown in FIG. 25, and hence the aperture ratio can be increased.

The above-described form is an upper concept extracted from the following three forms (1) to (3).

That is, the upper concept is formed such that all of configurations based on any of the three forms or all of configurations obtained by combining these forms with each other are included in the technical scope of the upper concept. The following three forms are: (1) a form which is configured such that, in each of pixels, a plurality of rectangular sub-pixels are arranged in a shape such as a stripe shape, such that, in each of the sub-pixels, the length of the short side of the rectangular shape is substantially the same, and such that, in at least one of the sub-pixels, the length of the long side of the rectangular shape is different; (2) a form which is configured such that each of sub-pixels is formed by sub-pixel electrodes, such as sub-picture elements, and such that, when alignment regulation means of liquid crystal molecules is provided in the sub-pixel electrode as in a CPA display mode, and the like, the distance between the alignment regulation means and the edge of the sub-pixel electrode is substantially the same in the sub-pixel electrodes of two or more of the sub-pixels in the same pixel; and (3) a form which is configured such that, when two or more kinds of alignment regulation means, such as a rib, and a slit, are provided in each of sub-pixel electrodes as in the MVA display mode, and the like, the distance between one kind of the alignment regulation means and the other kind of the alignment regulation means is substantially the same in the sub-pixel electrodes of two or more of the sub-pixels in the same pixel. In the present invention, any of the configurations based on any of the above-describe forms (1) to (3) or any of the configurations obtained by combining these forms with each other is preferred.

Note that any of the configurations based on any of the above-describe forms (1) to (3) or any of the configurations obtained by combining these forms with each other is one invention, and can be regarded as an invention independent of the present invention based on the upper concept described above or can be regarded as an invention dependent on the present invention.

The present invention can be applied to a panel using three primary colors, and can also be applied to a display panel using four or more primary colors, but it is preferred to apply the present invention to a display panel using four or more multiple primary colors. That is, a sub-pixel of a plurality of colors usually means a sub-pixel of three or more colors, and a sub-pixel of four or more colors is preferred in particular in order to exhibit the effects of the present invention. Note that the scope of the present invention is not limited only to the multi-primary color technique, and the effects of the present invention can also be exhibited, for example, in a form, and the like, in which multilayer columns are used in a liquid crystal display panel of a CPA mode, and the like.

That one pixel is formed by sub-pixels of a plurality of colors means that sub-pixels of a plurality of colors are arranged side by side on the panel surface so as to serve as one pixel for display. The array form of the sub-pixels of the plurality of colors may be a stripe-shape, or may be a two-by-two matrix-shape. The array form of the sub-pixels of the plurality of colors may also be a form of an array, such as a delta array, in which the sub-pixels are shifted in the column direction.

The pixel is not limited in particular as long as the region of the pixel is divided into a plurality of rectangular regions, but it is preferred that the region of the pixel is divided into a plurality of rectangular regions each of which has the same long side length and the same short side length. Further, a form is preferred in which the display panel is formed so that the long sides of the rectangular regions are arranged side by side in the same direction. Further, it is preferred that the display panel is formed so that each of the rectangular regions includes two or more sub-pixels. Further, a region including one pixel is divided into a plurality of rectangular regions. Usually, the region including the one pixel has a rectangular shape, and may include a part of the other pixel but does not include the other pixel as a whole. Further, it is preferred that the region has a minimum area among those substantially include the outer edge of the one pixel. In this specification, that a pixel or a sub-pixel is included in the region means that, as long as the operation effects of the present invention are exhibited, a pixel or a sub-pixel (hereinafter may also be referred to as a pixel, and the like) may be substantially included in the region, and a projecting portion, and the like, of a part of the pixel, and the like, may be made to project into the outside of the region, or a projecting portion, and the like, of a part of the other pixel, and the like, adjacent to the pixel may be made to enter into the region. Specific forms of the rectangular region will be described in detail in embodiments described below. One of the forms, in which the rectangular region is divided in this way, may be configured such that at least one of the rectangular regions is formed to include two or more sub-pixels, such that, in each of the sub-pixels, the length of the side in parallel with the short side direction of the rectangular region is the same, and such that, in the sub-pixel of at least one color, the length of the side in parallel with the long side direction of the rectangular region is different. With this form, the above-described operation effects of the present invention are exhibited.

The sub-pixel may have a rectangular shape, or a shape other than the rectangular shape (for example, a polygonal shape of pentagon or more, an elliptical shape, and the like), or may be a shape obtained by combining these shapes. Note that, as will be described below, one of the preferred forms of the present invention is a form in which the sub-pixel has a rectangular shape.

That the length in the direction in parallel with the direction of the short side of the rectangular region is the same includes a form in which the length is substantially the same, as long as the operation effects of the present invention are exhibited. Further, that, in the sub-pixel of at least one color, the length in the direction in parallel with the direction of the long side of the rectangular region is different means that the length may be the same for some colors, and that the length in the sub-pixel of at least one color may be different from the length in the sub-pixel of the other color.

That, the length of a side in parallel with the short side of the rectangular region is the same means that, when the length of the side in one sub-pixel is set to 100%, the difference between the length of the side of the rectangular shape in the one sub-pixel and the length of the side of the rectangular shape in the other sub-pixel is ±10% or less.

The above-described forms of the present invention will be described as follows with reference to conceptual diagrams. Note that the present invention is not limited to these conceptual forms.

Each of FIG. 26 to FIG. 28 conceptually represents one pixel. Each of FIG. 26 and FIG. 27 shows a form in which four rectangular sub-pixels are arranged in a stripe shape. FIG. 28 shows a form in which four rectangular sub-pixels or four polygonal sub-pixels are arranged in a two-by-two matrix shape.

In FIG. 26, each of the sub-pixels is formed by a plurality of sub-pixel electrodes such that the sub-pixel of red (R) consists of a sub-pixel electrodes of R1, R2 and R3, such that the sub-pixel of green (G) consists of sub-pixel electrodes of G1 and G2, such that the sub-pixel of blue (B) consists of sub-pixels B1, B2 and B3, and such that the sub-pixel of yellow (Y) consists of sub-pixel electrodes of Y1 and Y2. In FIG. 26, the region P surrounded by the dotted line, that is, the region including the sub-pixel electrodes of R1, R2, R3, G1 and G2, and the region of the gray (gray color) portion represent one rectangular region (P) at the time when a region including one pixel is divided into a plurality of rectangular regions. The region P′ surrounded by the dotted line, that is, the region including the sub-pixel electrodes of B1, B2, B3, Y1 and Y2, and the region of the gray portion represent one rectangular region (P′) at the time when the region including one pixel is divided into the plurality of rectangular regions. In the form shown in FIG. 26, each of the rectangular regions (P) and (P′) is formed so as to include two or more sub-pixels, and hence satisfies the configuration requirement that at least one rectangular region is to be formed so as to include two or more sub-pixels. Further, in the sub-pixel, the lengths of the sides in parallel with the short side of the rectangular region (P) are the same as each other. That is, with a view toward FIG. 26, in the sub-pixel electrodes R1 and G1, the length (a) and the length (b) of the sides in parallel with the side, which is the short side of the rectangular region (P) and which is located on the upper sides of the sub-pixel electrodes R1 and G1, are substantially equal to each other (the lengths a and b are substantially equal to each other). In the rectangular region (P′), similarly, the length (c) and the length (d) of the sides of the sub-pixel electrodes B1 and Y1 are substantially equal to each other (the lengths c and d are substantially equal to each other). It is preferred that in all the sub-pixels, the lengths of all the sides in parallel with the short side of the rectangular region are equal to each other, and that, in FIG. 26, all the lengths of a, b, c and d are equal to each other. Further, in the sub-pixel of red (R) and the sub-pixel of blue (B), the length of the side in parallel with the side, which is the long side of the rectangular region (P) and which is located on the left sides of the sub-pixel electrodes R1, R2 and R3, is set to e, while in the sub-pixel of green (G) and the sub-pixel of yellow (Y), the length of the side in parallel with the side, which is the long side of the rectangular region (P) and which is located on the left sides of the sub-pixel electrodes R1, R2 and R3, is set to f. Therefore, in at least one of the sub-pixels, the length of the side in parallel with the long side of the rectangular region is different. In this form, the lengths of the sides of the sub-pixels are also similarly set even on the basis of the side which is the long side of the rectangular region (P′) and which is located on the left side of the sub-pixel electrodes B1, B2 and B3.

The above-described rectangular region in the present invention is a region which is conceptually created in order to determine, in a region including one pixel, the shape and size of sub-pixels, and the shape, size, arrangement, and the like, of sub-pixel electrodes. Therefore, the sub-pixels and the sub-pixel electrodes can be designed by using the idea of this rectangular region.

In FIG. 27, each of the sub-pixels is formed by a plurality of sub-pixel electrodes such that the sub-pixel of red (R) consists of a sub-pixel electrode of R, such that the sub-pixel of green (G) consists of a sub-pixel electrode of G, such that the sub-pixel of blue (B) consists of a sub-pixel electrode of B, and such that the sub-pixel of yellow (Y) consists of a sub-pixel electrode of Y. In FIG. 27, the region Q surrounded by the dotted line, that is, the region including the sub-pixel electrodes of R and G, and the region of the gray portion represent one rectangular region (Q) at the time when a region including one pixel is divided into a plurality of rectangular regions. The region Q′ surrounded by the dotted line, that is, the region including the sub-pixel electrodes of B and Y, and the region of the gray portion represent one rectangular region (Q′) at the time when the region including one pixel is divided into the plurality of rectangular regions.

In FIG. 28, each of the sub-pixels is formed by a plurality of sub-pixel electrodes such that the sub-pixel of red (R) consists of sub-pixel electrodes of R1, R2 and R3, such that the sub-pixel of green (G) consists of sub-pixel electrodes of G1 and G2, such that the sub-pixel of blue (B) consists of sub-pixels B1, B2 and B3, and such that the sub-pixel of yellow (Y) consists of sub-pixel electrodes of Y1 and Y2. In FIG. 28, the region S surrounded by the dotted line, that is, the region including the sub-pixel electrodes of R1, R2, R3, G1 and G2, and the region of the gray portion represent one rectangular region (S) at the time when a region including one pixel is divided into a plurality of rectangular regions. The region S′ surrounded by the dotted line, that is, the region including the sub-pixel electrodes of B1, B2, B3, Y1 and Y2, and the region of the gray portion represent one rectangular region (S′) at the time when the region including one pixel is divided into the plurality of rectangular regions.

Also in the forms shown in FIG. 27 and FIG. 28, the configuration according to the present invention can be applied similarly to the form shown in FIG. 26.

Preferred forms of the display panel according to the present invention will be described in detail below.

It is preferred that the display panel is configured such that each of a plurality of sub-pixels has a rectangular shape, such that the long sides of the rectangular shapes are arranged side by side in the same direction, such that, in each of the sub-pixels, the length of the short side of the rectangular shape is substantially the same, and such that, in at least one of the sub-pixels, the length of the long side of the rectangular shape is different.

In this way, the form in which the sub-pixel itself also has a rectangular shape is preferred. The form in which the long sides of the rectangular shapes are arranged side by side in the same direction may be a form in which rectangular sub-pixels are arranged on both sides of the mutually adjacent long sides of the rectangular shapes, or may be a form in which the long sides of the rectangular shapes are arranged so as to be connected with each other (in other words, rectangular sub-pixels are arranged on both sides of the mutually adjacent short sides of the rectangular shapes). However, a form is preferred in which rectangular sub-pixels are arranged on both sides of the mutually adjacent long sides of the rectangular shapes. The same direction means to include a form in which the direction is substantially the same as long as the effects of the present invention are exhibited. Further, that the length of the short side of the rectangular shape is substantially the same means that, when the length of the short side of one sub-pixel is set to 100%, the difference in the length of the short side of the rectangular shape between the one sub-pixel and one of the other sub-pixels is about ±10% or less.

It is preferred that the display panel according to the present invention is configured such that each of a plurality of sub-pixels is formed by sub-pixel electrodes each having alignment regulation means, such that at least one of the sub-pixels includes two or more sub-pixel electrodes, and such that, in plan view of the pixel in the display panel, the distance between the alignment regulation means and the edge of the sub-pixel electrode is substantially the same in the sub-pixel electrodes in the two or more sub-pixels in the same pixel.

When a sub-pixel of each color has a plurality of sub-pixel electrodes in this way, the sub-pixel electrodes may be driven by the same TFT, or may be respectively driven by different TFTs driven by the same signal line (source bus line) and the same scanning line. Further, it is particularly preferred that the area (size) of each of the sub-pixel electrodes is set to be substantially the same (approximately the same), and that the display pixel area of each color is changed by changing the number of sub-pixel electrodes included in the sub-pixel of each color. The alignment regulation means is usually a projecting structure, a cut-out portion of the common electrode, or a stepped portion (usually a recess) which is provided on the insulator. Further, that substantially the same in the above means that, when, in one sub-pixel electrode in the same pixel, the distance between the alignment regulation means and the edge of the sub-pixel electrode is set to 100%, the difference between this distance and the distance between the alignment regulation means and the edge of the sub-pixel electrode in the other sub-pixel electrode in the same pixel is ±10% or less. In such form, especially in a liquid crystal display panel of a CPA mode, and the like, the alignment state is made more uniform, so that the difference in the response speed characteristic between the sub-pixels can be sufficiently reduced and further the viewing angle characteristic can be sufficiently improved.

It is preferred that the above-described display panel is configured such that each of the plurality of sub-pixels is formed by sub-pixel electrodes having two or more kinds of alignment regulation means, and such that, in plan view of the pixel in the display panel, the distance between one kind of alignment regulation means and the other kind of alignment regulation means is substantially the same in the sub-pixel electrodes in the two or more sub-pixels in the same pixel.

It is preferred that each of the sub-pixels includes one sub-pixel electrode. A form is preferred in which the one kind of alignment regulation means and the other kind of alignment regulation means are ribs that are in parallel with each other, or are cut-out portions and slits, that are in parallel with each other, of an opposed common electrode, or are the edges of the pixel electrodes, which edges are provided in parallel with each other. Further, that substantially the same in the above means that, when the distance between one kind of alignment regulation means and the other kind of alignment regulation means in one sub-pixel electrode in the same pixel is set to 100%, the difference between this distance and the distance between one kind of alignment regulation means and the other kind of alignment regulation means in the other sub-pixel electrode in the same pixel is ±10% or less. In such form, especially in a liquid crystal display panel of an MVA mode, and the like, the alignment state can be made more uniform, so that the difference in the response speed characteristic between sub-pixels can be sufficiently reduced and the view angle characteristic can be sufficiently improved.

It is preferred that, in plan view of the main surface of the panel, the pixel has a rectangular light shielding region in a region that is included in the display region and that is other than the region in which the sub-pixel is arranged. The rectangular shape in the above may be a shape having a projection and/or a recess or may be substantially a rectangular shape, as long as the effects of the present invention are exhibited. In other words, a form is preferred in which in the sub-pixel of at least one color, the length of the side in parallel with the long side of the rectangular shape is different, and in which the light shielding region is arranged in a space that is formed in correspondence with the reduced length of the side of the sub-pixel (electrode). For example, when the patterns of non-transmissive portions, such as TFTs element and contact holes, of the sub-pixel having more sub-pixel electrodes are arranged in the non-transmissive region of the sub-pixel having less sub-pixel electrodes, the aperture ratio, especially the aperture ratio of the sub-pixel having the large side length can be improved. A form is preferred in which a thin-film transistor is arranged in the light shielding region.

A form is preferred in which a columnar spacer is arranged in the light shielding region. Especially, when a multilayer column is used as cell thickness retaining means, a form is preferred in which a multilayer column is arranged in a portion of a sub-pixel having a small area, in which portion a sub-pixel electrode is not arranged.

Further, a form is preferred in which a sub-pixel electrode and/or a storage capacitance wiring are arranged in the light shielding region. With such form, it is possible to sufficiently prevent that the aperture ratio is reduced by the columnar spacer, the sub-pixel electrode, and/or the storage capacitance wiring. Further, when a columnar spacer is arranged in a portion where the pixel electrode is not arranged, it is possible to avoid the vertical leakage (leakage between the sub-pixel electrode and the opposed common electrode (COM electrode)). Especially, when the sub-pixel is small, the form in which the columnar spacer, the sub-pixel electrode, and/or the storage capacitance wiring are arranged in the light shielding region is particularly preferred.

Further, it is preferred that, in the display panel, the polarity of the potential of the sub-pixel electrode for display of each color is reversed at every natural number multiple of the number of sub-pixels included in one pixel in the same row direction. This form is particularly preferred when even number of sub-pixels are arranged per one pixel in the same row direction. In this way, when the measure is taken to prevent the same polarity of the potential of the sub-pixel electrode from being laterally arranged side by side at the time of monochromatic display, it is possible to avoid the lateral shadow. The above-described form may be based on a driving method, or may also be based on a design.

In the display panel in which one of the pair of substrates includes scanning lines, signal lines, storage capacitance wirings, thin-film transistors each connected to each of the scanning line and the signal line, and sub-pixel electrodes each connected to each of the thin-film transistors, in which the other of the pair of substrates includes a common electrode, in which the sub-pixel electrodes are arranged in correspondence with one sub-pixel, in which the scanning line and the sub-pixel electrode form gate-drain capacitance Cgd, and the signal line and the sub-pixel electrode form source-drain capacitance Csd, and in which the storage capacitance wiring and the sub-pixel electrode form storage capacitance Ccs, and the sub-pixel electrode and the common electrode form liquid crystal capacitance Clc, it is preferred that, when a potential difference between the scanning lines at the time of driving the display panel is set as Vg^{p-p}, at least one of the pull-in voltage ΔVd=Cgd/(Cgd+Csd+Ccs+Clc)×Vg^{p-p}, the difference Ω in the value of ΔVd value between the time of white display and the time of black display, and the value of Ccs/Clc is the same for each color. Specifically, it is preferred that at least one of the size of the switching element and the value of the storage capacitance of the sub-pixel having the large area is larger than at least one of the size of the switching element and the value of the storage capacitance of the sub-pixel having the small area. With such form, at least one of the value of ΔVd, the value of Ω, and the value of Ccs/Clc can be made substantially the same for all the colors. Note that the above-described form in which “at least one of the size of the switching element and the value of the storage capacitance of the sub-pixel having the large area is larger than at least one of the size of the switching element and the value of the storage capacitance of the sub-pixel having the small area” means a form in which the size of the switching element of the sub-pixel having the large area is larger than the size of the switching element of the sub-pixel having the small area, or a form in which the value of the storage capacitance of the sub-pixel having the large area is larger than the value of the storage capacitance of the sub-pixel having the small area, or a form in which these forms are combined together. Thereby, the difference in the ratios of the optimum opposed voltage and the storage capacitance between the colors are eliminated, so that excellent panel quality without image persistence, and the like, can be obtained. Note that the potential difference Vg^{p-p} of a scanning line is expressed as |Vgh-Vgl| (where Vgh represents the highest voltage in the scanning line at the time of turning on and off the TFT, and Vgl similarly represents the lowest voltage in the scanning line). Further, the difference Ω in the value of ΔVd between the time of white display and the time of black display is a difference in the value ΔVd between the time of white display and the time of black display, which difference is caused due to the difference in the capacitance in the liquid crystal between the time of white display and the time of black display. The difference Ω in the value of ΔVd between the time of white display and the time of black display is obtained by the following expression: Ω=|ΔVd (black)−ΔVd (white)|=|Cgd/(Cgd+Csd+Ccs+Clc (black))×Vg^{p-p}−Cgd/(Cgd+Csd+Ccs+Clc (white))×Vg^{p-p}|. Note that Clc (black) means the value of Clc at the time of black display, and Clc (white) means the value of Clc at the time of white display.

In the above-described forms, the form is particularly preferred in which the sub-pixel electrode and the storage capacitance (storage capacitance wiring) of the sub-pixel having the small area are provided in the portion (rectangular region) of the sub-pixel having the small area, in which portion the sub-pixel electrode is not arranged. Thereby, the aperture portion of the sub-pixel having the small area can be substantially enlarged, and a liquid crystal display device having high luminance can be obtained.

It is preferred that the sub-pixel includes a plurality of sub-pixel electrodes, each having the same area, and that, in the sub-pixel of at least one color, the number of the sub-pixel electrodes is different. Thereby, in various liquid crystal display devices, the difference in the response speed characteristic between the sub-pixels can be sufficiently reduced by making the alignment state more uniform, and also the luminance can be sufficiently increased by changing the areas of the sub-pixels. That the area of the sub-pixel electrode is the same in the above means that the area may be substantially the same as long as the effects of the present invention can be substantially exhibited.

It is preferred that a display panel according to the present invention is a liquid crystal display panel including a pair of substrates and a liquid crystal layer sandwiched between the pair of substrates. In other words, it is preferred that a display panel according to the present invention is a liquid crystal display panel using a liquid crystal layer as a display element. When the present invention is applied to a liquid crystal display panel, the effects of the present invention can be more sufficiently exhibited. The display panel according to the present invention can be applied to a CPA mode, and a MVA mode. Also, when the display panel according to the present invention is applied to a TN (Twisted Nematic) mode, the effects of the present invention, such as the effect of simplifying the manufacturing of a sub-pixel having a small area, and the effect of improving the yield, can be more sufficiently exhibited. Further, the display panel according to the present invention can also be suitably applied to TBA (Transverse Bend Alignment) modes and IPS modes such as FFS (Frings Field Switching) modes. In particular, the present invention is suitably applied to a vertical liquid crystal mode (in which liquid crystal molecules are aligned substantially vertically to the substrate surface at the time of no voltage application, and the present invention is particularly suitably applied to a CPA mode). When multi-primary color display is performed in the CPA mode, and when the aperture ratio is changed for each color, the technique according to the present invention is inevitably used.

Also, the present invention provides a display device including the display panel according to the present invention.

Thereby, the same effects as the above-described display panel according to the present invention can be exhibited. Further, preferred forms of the display panel provided in the display device according to the present invention are the same as the above-described preferred forms of the display panel according to the present invention.

The display panel and the display device according to the present invention are preferably used in medium-size products, such as electronic books, photo frames, IAs, and PCs.

The aforementioned modes may be employed in appropriate combination as long as the combination is not beyond the spirit of the present invention.

### Advantageous Effects of Invention

With the display panel and the display device according to the present invention, it is possible that the luminance is sufficiently improved, and also an excellent manufacturing yield is obtained, and that the difference in the response speed characteristic between the colors is sufficiently reduced, and also the view angle characteristic is sufficiently improved.

### BRIEF DESCRIPTION OF DRAWINGS

FIG. 1 is a schematic plan view showing a liquid crystal display panel of Embodiment 1-1.

FIG. 2 is a view in which the black matrix is omitted in FIG. 1.

FIG. 3 is a schematic plan view showing a liquid crystal display panel of Embodiment 1-2.

FIG. 4 is a view in which the black matrix is omitted in FIG. 3.

FIG. 5 is a schematic plan view showing sub-pixel electrodes of the liquid crystal display panel of Embodiment 1-1.

FIG. 6 is a schematic plan view showing a modification (embodiment 1-3) of the liquid crystal display panel of Embodiment 1-1.

FIG. 7 is a schematic plan view showing a modification (embodiment 1-4) of the liquid crystal display panel of Embodiment 1-1.

FIG. 8 is a schematic plan view showing a liquid crystal display panel of Embodiment 2-1.

FIG. 9 is a view in which the black matrix is omitted in FIG. 8.

FIG. 10 is a schematic plan view showing a liquid crystal display panel of Embodiment 2-2.

FIG. 11 is a view in which the black matrix is omitted in FIG. 10.

FIG. 12 is a schematic plan view showing a liquid crystal display panel of Embodiment 3.

FIG. 13 is a view showing only alignment regulation means provided in the sub-pixel electrodes of the sub-pixels and in the common electrodes in FIG. 12.

FIG. 14 is a view showing only the sub-pixel electrodes of the sub-pixels and the signal lines in FIG. 12.

FIG. 15 is a schematic plan view showing a liquid crystal display panel of Embodiment 4.

FIG. 16 is a view showing only alignment regulation means provided in the sub-pixel electrodes of the sub-pixels and in the common electrodes in FIG. 15.

FIG. 17 is a view showing only the sub-pixel electrodes of the sub-pixels and the signal lines in FIG. 15.

FIG. 18 is a schematic cross-sectional view showing a liquid crystal display panel of Embodiments 3 and 4.

FIG. 19 is a schematic plan view showing a liquid crystal display panel in which one pixel is formed by conventional sub-pixels arranged in a stripe shape of three colors.

FIG. 20 is a schematic plan view showing a liquid crystal display panel in which one pixel is formed by conventional sub-pixels arranged in a stripe shape of four colors.

FIG. 21 is a schematic plan view showing a liquid crystal display panel in which the area ratio between respective sub-pixel electrodes is changed in the liquid crystal display panel shown in FIG. 20.

FIG. 22 is a schematic plan view showing a liquid crystal display panel in which one pixel is formed by conventional sub-pixels arranged in a two-by-two matrix shape of four colors.

FIG. 23 is a schematic plan view showing a liquid crystal display panel in which the area ratio between respective sub-pixel electrodes is changed in the liquid crystal display panel shown in FIG. 22.

FIG. 24 is a schematic plan view showing a liquid crystal display panel in which the area ratio between respective sub-pixel electrodes is changed in the liquid crystal display panel.

FIG. 25 is a schematic plan view showing a liquid crystal display panel in which the area ratio between respective sub-pixel electrodes is changed in the liquid crystal display panel.

FIG. 26 is a conceptual diagram showing a form in which four rectangular sub-pixels are arranged in a stripe shape.

FIG. 27 is a conceptual diagram showing a form in which four rectangular sub-pixels are arranged in a stripe shape.

FIG. 28 is a conceptual diagram showing a form in which four rectangular sub-pixels or four polygonal sub-pixels are arranged in a two-by-two matrix shape.

### DESCRIPTION OF EMBODIMENTS

Note that a substrate provided with TFTs is also referred to as a TFT array substrate. A substrate which is provided with a color filter (CF) and which faces the TFT array substrate is also referred to as an opposed substrate or a CF substrate. Further, in the following embodiments, for the sake of brevity of description, a sub-pixel representing each color is also referred to simply as a pixel. In the following, only a form using RGBY is described, but instead of RGBY, a form using four primary colors, such as RGBW, or more can be suitably applied.

The present invention will be mentioned in more detail referring to the drawings in the following embodiments, but is not limited to these embodiments. For example, in the following, a liquid crystal display panel and a liquid crystal display device will be described, but the present invention includes a portion applicable to other display panels, such as an organic electroluminescence display panel.

### Embodiment 1

Embodiment 1 relates to a form in which sub-pixels are arranged in a stripe shape in a liquid crystal display panel of a CPA mode.

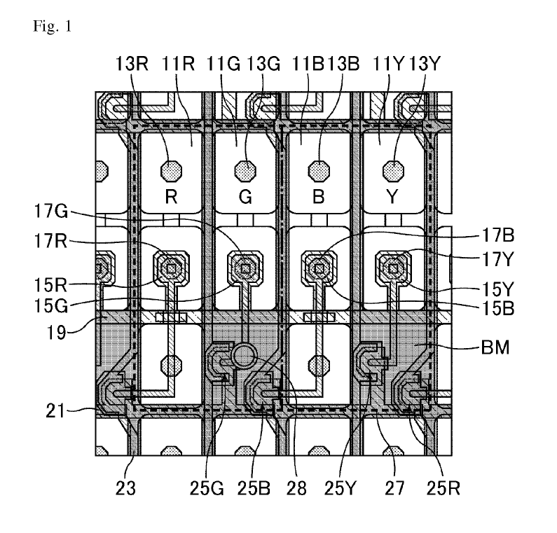

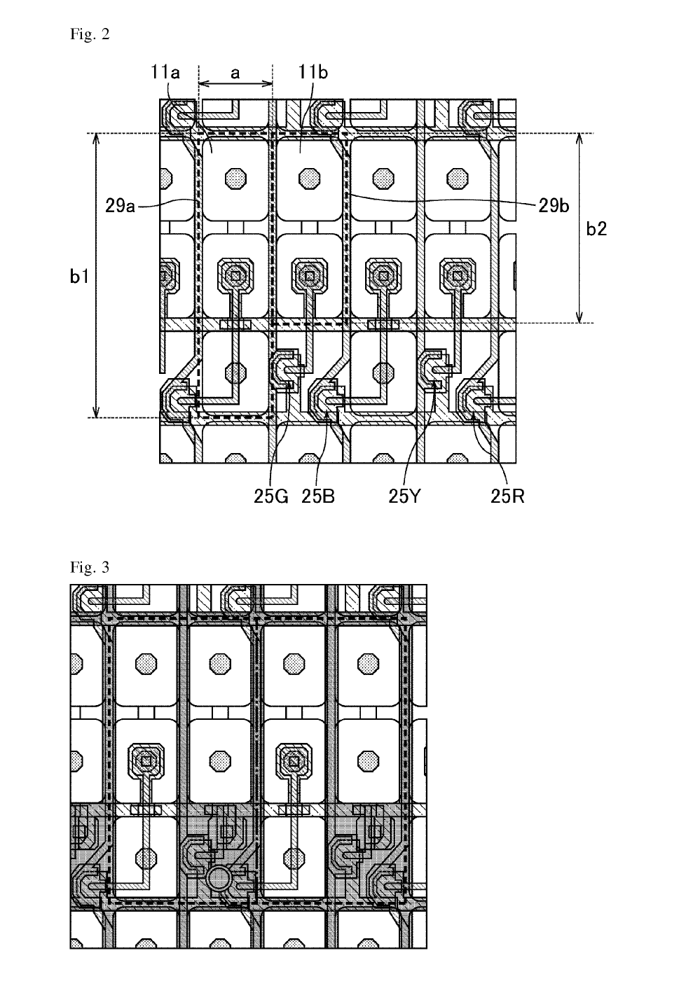

FIG. 1 is a schematic plan view showing a liquid crystal display panel of Embodiment 1-1. FIG. 2 is a view in which the black matrix is omitted in FIG. 1. The liquid crystal display panel of Embodiment 1 has following features.

Scanning lines 21 and signal lines 23 are arranged in a grid shape on the main surface of a glass substrate, and a Cs wiring 19 is arranged between the scanning lines 21 adjacent to each other so as to be in parallel with the scanning line 21.

In each of a plurality of pixel regions divided by the scanning lines 21 and the signal lines 23, three sub-pixel electrodes 11R are arranged in the pixel region of red (R), two sub-pixel electrodes 11G are arranged in the pixel region of green (G), three sub-pixel electrodes 11B are arranged in the pixel region of blue (B), and two sub-pixel electrodes 11Y are arranged in the pixel region of yellow (Y). A unit pixel 27 is formed by these four pixel regions. Note that each of the sub-pixel electrodes has substantially the same area for each color. Each of the unit pixels 27 is divided into rectangular regions respectively including sub-pixel electrodes for displaying a plurality of colors. The number of sub-pixel electrodes is changed for each color. As a result, the area of the effective aperture portion is different for each color. Here, it is preferred to set the difference in the effective aperture area according to the difference in the luminosity factor (brightness) and/or the color purity (saturation) between colors, and according to required characteristics of the panel. Usually, the effective aperture area is changed between a color having a comparatively high luminosity factor and a color having a comparatively low luminosity factor. That is, the effective aperture area of a color having a comparatively high luminosity factor is made small, and the effective aperture area of a color having a comparatively low luminosity factor is made large. Specifically, when the broken-dotted line for equally dividing the unit pixel 27 shown in FIG. 1 in the longitudinal direction is taken as a boundary, and when the unit pixel 27 is divided into the rectangular region consisting of the pixel region of red (R) and the pixel region of green (G), and the rectangular region consisting of the pixel region of blue (B) and the pixel region of yellow (Y), the rectangular region on the left side in FIG. 1 is formed so as to include two sub-pixels (R and G), and the rectangular region on the right side in FIG. 1 is formed so as to include two sub-pixels (B and Y). That is, in FIG. 1, the portion, which is surrounded by the broken lines indicating the unit pixel 27 and by the broken-dotted line equally dividing the unit pixel 27 in the longitudinal direction, is the rectangular region in Embodiment 1-1, and the same is also applied to the other embodiments. Further, in the sub-pixels R, G, B and Y (for example, the sub-pixel of R is denoted by reference character 29a, and the sub-pixel of G is denoted by reference character 29b), the length a of the side (the side in the lateral direction in FIG. 2) in parallel with the short side of the rectangular region is substantially the same, and the length b1 of the sides of the sub-pixels R and B and the length of b2 of the sides of the sub-pixels G and Y, which sides are (the sides in the longitudinal direction in FIG. 2) in parallel with the long side of the rectangular region, are different from each other. Note that the effect of the present invention, such as the effect of improving white luminance by changing (increasing) the number of sub-pixel electrodes depending on colors as in the present embodiment, can be exhibited also in a display panel using three colors.

Each of the sub-pixel of red (R) and the sub-pixel of blue (B) is formed by arranging three sub-pixel electrodes in parallel with the long side of the rectangular sub-pixel electrode, while each of the sub-pixel of green (G) and the sub-pixel of yellow (Y) is formed by arranging two sub-pixel electrodes in parallel with this direction. Note that, in FIG. 2, the longitudinal length b1 of the sub-pixel of red (R) and the sub-pixel of blue (B) is about 3/2 of the longitudinal length b2 of the sub-pixel of green (G) and the sub-pixel of yellow (Y).

Further, in the display panel shown in FIG. 1, each of the plurality of sub-pixels RGBY has a (substantially) rectangular shape but may have a substantially elliptical shape. Especially, a rectangular shape is preferred, and it is preferred that the pixel is formed in such a manner that the long sides of the rectangular sub-pixels RGBY are arranged side by side substantially in the same direction, more particularly, that the rectangular sub-pixels RGBY are arranged so as to sandwich (on both sides of) the mutually adjacent long sides of the rectangular sub-pixels. It is preferred that, in the sub-pixels RGBY, the length of the short side of the rectangular shape is substantially the same, and that the length of the long side of the rectangular sub-pixels R and B is different from the length of the long side of the rectangular sub-pixels G and Y.

The opposed substrate is configured such that a red (R) CF layer, a green (G) CF layer, a blue (B) CF layer, and a yellow (Y) CF layer are arranged on the main surface of a glass substrate respectively in correspondence with the pixel regions, and a light shielding portion (hereinafter may also be referred to as BM), which is referred to as a black matrix, is provided to partition the respective CF layers. Further, a rectangular BM is also arranged in the region which is located on the lower side of the sub-pixel having the small area in FIG. 1 and FIG. 2 and in which the sub-pixel electrode is not provided. Further, as shown in FIG. 2, under the BM of the sub-pixel (G), not only the TFT 25G of the sub-pixel (G) but also the TFT 25B of the sub-pixel (B) adjacent to the sub-pixel (G) are arranged, while under the BM of the sub-pixel (Y), not only the TFT 25Y of the sub-pixel (Y) but also the TFT 25R of the sub-pixel (R) on the right side of Y adjacent to the sub-pixels (Y) are arranged. Further, a photo spacer 28 is also arranged under the BM.

Further alignment regulation means 13R, 13G, 13B and 13Y are formed on the opposed substrate.

In the display panel, the plurality of sub-pixels RGBY are respectively formed by the sub-pixel electrodes 11R, 11G, 11B and 11Y respectively provided with alignment regulation means 13R, 13G, 13B and 13Y. In plan view of the pixel in the display panel, the distance between each of the alignment regulation means 13R, 13G, 13B and 13Y and the edge of each of the sub-pixel electrodes 11R, 11G, 11B and 11Y is substantially the same. Each of the alignment regulation means 13R, 13G, 13B and 13Y is formed as a projecting structure, a stepped portion provided on an insulator (usually, a recess provided on an insulator on the side of a TFT array substrate), or cut-out portion (notch) of the common electrode. For example, each of the alignment regulation means 13R, 13G, 13B and 13Y is formed as, a projecting portion or a stepped portion, the bottom portion of each of which has a circular shape, an elliptic shape, a bar shape, a Y-shape or has a shape formed by combining a Y-shape and an inverse Y-shape. Alternatively, each of the alignment regulation means 13R, 13G, 13B and 13Y is formed as a cut-out portion having the similar shape in the common electrode.

Further, in the TFT array substrate, a wiring extracted from the drain electrode of each of the TFTs is connected to each of the sub-pixel electrodes 11R, 11G, 11B and 11Y via each of contact holes 17R, 17G, 17B and 17Y, and further is connected to each of CS (storage) capacitance 15R, 15G, 15B and 15Y provided on CS (storage capacitance) wiring 19.

Further, the liquid crystal display panel of Embodiment 1-1 has the following features.

The length of each of the sides of the sub-pixel electrode for each color, which sides are respectively in parallel with the long side and the short side of the rectangular region, is substantially the same, and the difference in the length of each of the long and short sides between the colors is about ±10% or less. Further, the area of the sub-pixel electrode for each of the colors is substantially the same, and the difference in the area of the sub-pixel electrode between the colors is about ±20% or less because the difference in the lengths of each of the sides between the colors is about ±10% or less. For example, in FIG. 5 which is a schematic plan view showing the sub-pixel electrodes of the liquid crystal display panel of Embodiment 1-1, when the length A of the sub-pixel electrode is set to 100%, the difference between the length A of the sub-pixel electrode and the length A′ of the sub-pixel electrode is ±10% or less. When the length B of the sub-pixel electrode is set to 100%, the difference between the length B of the sub-pixel electrode and the length B′ of the sub-pixel electrode is ±10% or less. Further, when the area of the sub-pixel electrode having the length A and the length B is set to 100%, the difference between the area of the sub-pixel electrode having the length A and the length B and the area of the sub-pixel electrode having the length A′ and the length B′ is ±20% or less.

The panel is formed by four colors, such as RGBY and RGBW. In the case of RGBY, it is effective that the area of the sub-pixels R and B, each of which has a low luminosity factor, is increased, and that the area of the sub-pixels of G and Y, each of which has a high luminosity factor, is reduced. This is because, with this arrangement, the transmissivity is improved, and the color reproduction range can be expanded. The ratio of the areas is in the range of RB:GY (RB:GW)=4:1 to 1:1, more preferably, in the range of RB:GY (RB:GW)=2.2:1 to 1.2:1.

Further, the liquid crystal display panel of Embodiment 1-1 has the following features.

The sub-pixel electrodes of the same color may be electrically connected to each other, or may be connected to different TFTs which are driven by the same scanning line and the same signals line, and may not be electrically connected to each other.

A rectangular BM is arranged in the region of the sub-pixel having the small sub-pixel electrode, in which region the sub-pixel electrode is not provided. Under the BM arranged in this region, the contact hole, the TFT, the CS (storage) capacitance, the photo spacer 28, the pixel electrode, the bus line, and the like, can be arranged.

In this BM region, not only the TFT of the sub-pixel having the BM, but also the contact hole, the TFT, the CS capacitance, the bus line, and the like, of the sub-pixel adjacent to the sub-pixel having the BM may also be arranged. Thereby, the aperture ratio of the sub-pixel having the BM and the sub-pixel adjacent to the sub-pixel having the BM can be suitably increased. Note that FIG. 1 shows a form in which not only the TFT of the sub-pixel having the BM but also the TFT of the sub-pixel adjacent to the sub-pixel having the BM are arranged under the BM.

Further, in the display panel, the lateral shadow (cross talk) can be avoided in such a manner that the polarity of the same color on the same row is made uniform, that is, in such a manner that the polarity of the potential of the sub-pixel electrode for display of each color is reversed at every natural number multiple of the number of sub-pixels included in one pixel in the same row direction.

The liquid crystal display panel of Embodiment 1-1 includes a pair of substrates, and a liquid crystal layer sandwiched between the pair of substrates. In other words, the liquid crystal display panel of Embodiment 1-1 includes a first substrate (array substrate), a second substrate (opposed substrate), and a liquid crystal layer sandwiched between the first substrate and the second substrate. The first substrate includes the plurality of scanning lines 21/the plurality of signal lines 23/switching elements (TFT 25R, and the like)/an interlayer dielectric/sub-pixel electrodes on the interlayer dielectric in this order from the side of the substrate. Further, the first substrate includes a vertical alignment layer provided on the sub-pixel electrode. The second substrate includes the common electrode, and the alignment regulation means 13R, and the like (a projecting structure and/or a cut-out portion of the common electrode), and a vertical alignment layer. Further, especially in the CPA mode, the stepped portion (usually a recess) provided, as alignment regulation means, on the insulator on the side of the TFT array substrate is useful, and when the stepped portion is used, it is not necessary that the alignment regulation means is arranged on the common electrode as described above. In other words, in addition to the alignment regulation means on the common electrode or instead of the alignment regulation means on the common electrode, the stepped portion (usually a recess) provided on the insulator on the side of the TFT array substrate can be used. From the viewpoint that members and a manufacturing process can be omitted, the form is preferred in which the stepped portion (usually a recess) provided on the insulator on the side of the TFT array substrate is used instead of the alignment regulation means on the common electrode. The liquid crystal layer is made of a liquid crystal material having negative dielectric anisotropy.

The liquid crystal display panel of Embodiment 1-1 is configured such that at least one of the size of the switching element and the value of the storage capacitance of a sub-pixel having a large area is larger than at least one of the size of the switching element and the value of the storage capacitance of a sub-pixel having a small area.

Thereby, when the gate-drain capacitance formed by the scanning line and the sub-pixel electrode is set as Cgd, and the source-drain capacitance formed by the signal line and the sub-pixel electrode is set as Csd, when the storage capacitance formed by the storage capacitance wiring and the sub-pixel electrode is set as Ccs, and the liquid crystal capacitance formed by the sub-pixel electrode and the common electrode is set as Clc, and when the potential difference between the scanning lines at the time of driving the display panel is set as Vg^{p-p}, the pull-in voltage ΔVd=Cgd/(Cgd+Csd+Ccs+Clc)×Vg^{p-p}, the difference Ω in the value of ΔVd between the time of white display and the time of black display, and the value of Ccs/Clc are the same for each of the colors.

Note that each of the potential difference Vg^{p-p} of a scanning line and the difference Ω in the value of ΔVd between the time of white display and the time of black display is the same as that described above.

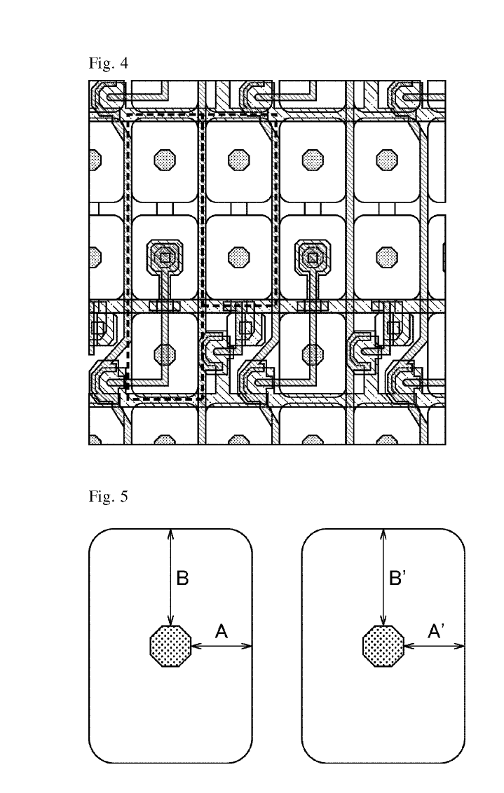

FIG. 3 is a schematic plan view showing a liquid crystal display panel of Embodiment 1-2. FIG. 4 is a view in which the black matrix is omitted in FIG. 3. Embodiment 1-2 is a form in which, in Embodiment 1-1, the contact hole, the CS (storage) capacitance, and the photo spacer of the sub-pixel having the BM are additionally arranged under the BM. The other configuration of Embodiment 1-2 is the same as the configuration of Embodiment 1-1.

The effects of Embodiment 1-1 and Embodiment 1-2 are described on the basis of the results estimated when the size of one pixel is set to 180 μm.

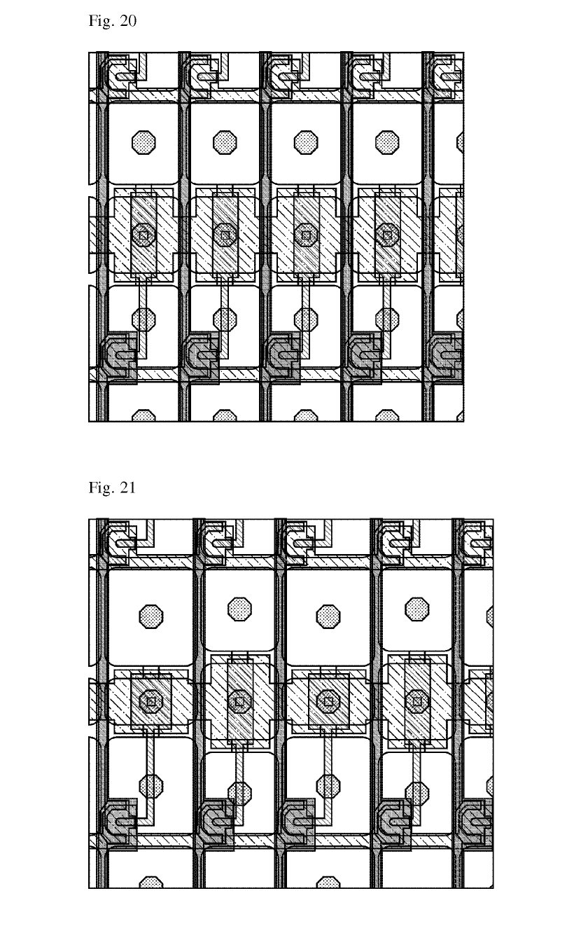

In the conventional art, when a display panel using three colors of RGB is made to correspond to four colors of RGBY (for example, as in FIG. 20), the CF transmissivity is improved. However, since the display panel using three primary colors of RGB is made to correspond to the four primary colors of RGBY, the aperture ratio is reduced, and thereby the transmissivity improvement rate remains at only 8%. Also, there arises a problem that the luminance of monochromatic color and complementary color is reduced (the reduction in the luminance is remarkably visually recognized especially in R and M (magenta)).

Note that, as for the luminance, for example, in G, B and C (cyan) other than R and M, the reduction in luminance in natural images is a visually unrecognizable level. Further, the luminance in Y is improved because, in addition to the luminance in Y (when the Y picture element is turned on), the luminance in R+G (when the R picture element and the G picture element are turned on at the same time) contributes as the luminance in Y. Here, since the color Y can be formed by turning on the Y picture element and by turning on the R picture element and the G picture element at the same time, the luminance of Y can be increased more as compared with the area of the Y picture element itself. On the other hand, the luminance of each of the monochromatic colors (R, G, B, C (=B+G), M(=R+B)) other than Y is obtained only in correspondence with the area of each of the picture elements, and hence the problem as described above is caused.

When the ratio of the areas is set as RB:GY=1.5:1 to improve the luminance of monochromatic color and complementary color (for example, as in FIG. 21), the transmissivity is rather reduced as compared with the case of the display panel using three colors of RGB. Further, the size of the sub-pixel electrode (the length of the short side of the sub-pixel electrode) is significantly different between RB and GY (RB: 45 μm, GY: 31 μm), and hence there remains a problems that the response speed and visual characteristics are changed for each color.

### Embodiment 1-1

In Embodiment 1-1, in the state where the areas of the sub-pixel electrodes for respective colors are made equal to each other, when a rectangular BM is arranged in the region which is included in a sub-pixel having a small area ratio and in which the sub-pixel electrode is not arranged, and when a TFT of a sub-pixel adjacent to the sub-pixel having the BM is arranged in the region, the transmissivity not less than the transmissivity obtained in the display panel using RGB can be secured. When Y is further added, the color reproduction range is expanded by 5%. In this way, both the color reproduction range and the transmissivity can be improved. The sizes of the sub-pixel electrodes for respective colors are made equal to each other, and hence the difference in the response speed and visual angle characteristics between the colors is not recognized.

### Embodiment 1-2

In Embodiment 1-2, when, under the BM arranged in the region of the sub-pixel in which region the sub-pixel electrode is not arranged, the TFT of the sub-pixel adjacent to the sub-pixel having the BM, and the contact hole and the CS capacitance of the sub-pixel having the BM are arranged, the transmissivity can be improved by 10% or more as compared with the case of the display panel using RGB. When Y is further added, the color reproduction range is expanded by 5%. In this way, both the color reproduction range and the transmissivity can be improved. The sizes of the sub-pixel electrodes for respective colors are made equal to each other, and hence the difference in the response speed and visual angle characteristics between the colors is not recognized.

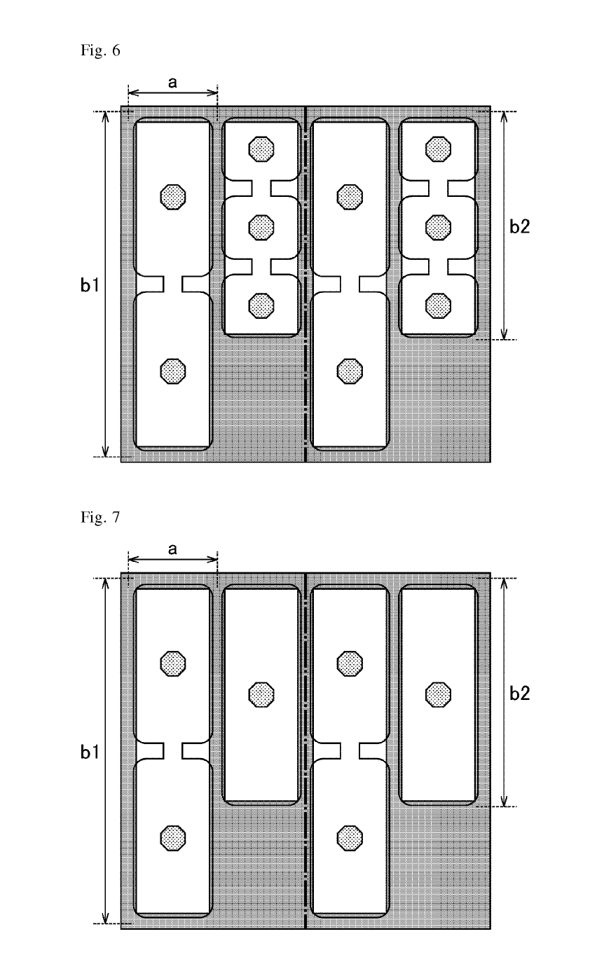

FIG. 6 is a schematic plan view showing a modification (embodiment 1-3) of the liquid crystal display panel of Embodiment 1-1. FIG. 7 is a schematic plan view showing a modification (embodiment 1-4) of the liquid crystal display panel of Embodiment 1-1. Each of FIG. 6 and FIG. 7 schematically shows only sub-pixel electrodes in a pixel. In Embodiment 1-3 and Embodiment 1-4, the display panel is configured such that, when one pixel is equally divided into two rectangular regions by the broken-dotted line that is a longitudinal line, each of the rectangular regions includes two sub-pixels. In the sub-pixels, the length a of the side in parallel with the short side of the rectangular region is substantially the same. In at least a pair of the sub-pixels, the lengths b1 and b2 of the sides in parallel with the long side of the rectangular region are different from each other, and the sizes of the sub-pixel electrodes of the sub-pixels are different from each other. In Embodiment 1-3 and 1-4 configured in this way, differences in the response speed and visual angle characteristics between the colors are recognizable, and hence Embodiment 1-3 and 1-4 are slightly inferior to Embodiment 1-1 and Embodiment 1-2.

### Embodiment 2

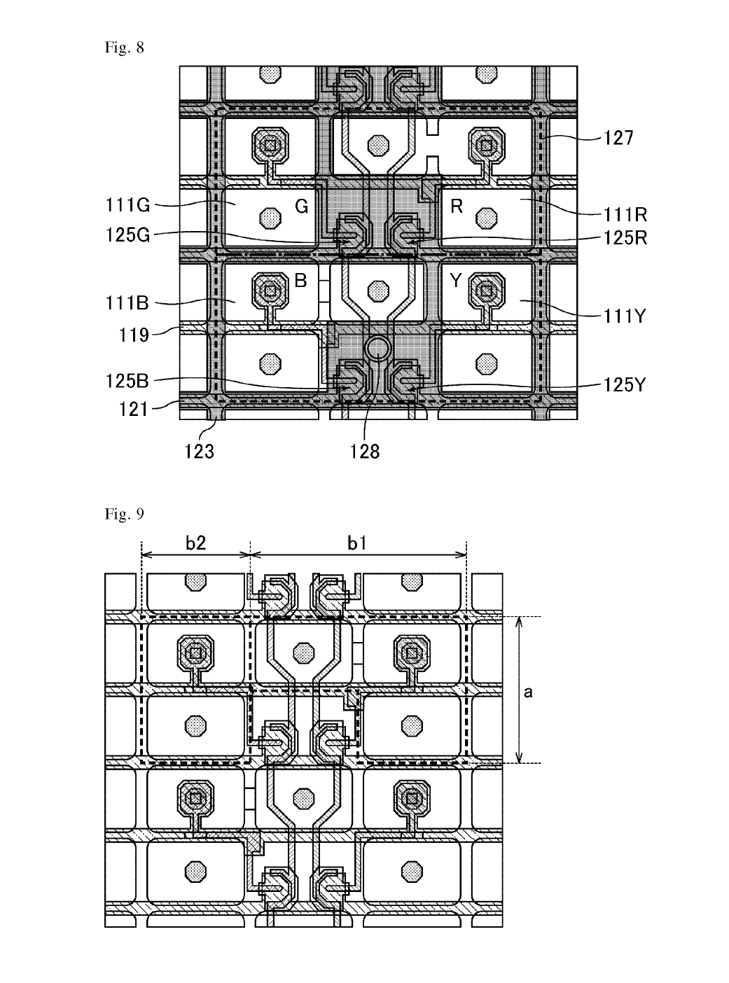

FIG. 8 is a schematic plan view showing a liquid crystal display panel of Embodiment 2-1. FIG. 9 is a view in which the black matrix is omitted in FIG. 8. Embodiment 2 relates to a CPA mode liquid crystal display panel in which sub-pixels are arranged in a two-by-two matrix shape.

Scanning lines 121 and signal lines 123 are arranged in a grid shape on the main surface of a glass substrate, and a Cs wiring 119 is arranged between scanning lines 121 adjacent to each other so as to be in parallel with the scanning line 121.

In each of a plurality of pixel regions divided by the scanning lines 121 and signal lines 123, three sub-pixel electrodes 111R are arranged in a pixel region of red (R), two sub-pixel electrodes 111G are arranged in a pixel region of green (G), three sub-pixel electrodes 111B are arranged in a pixel region of blue (B), and two sub-pixel electrodes 111Y are arranged in a pixel region of yellow (Y). A unit pixel 127 is formed by these four pixel regions. Note that the sub-pixel electrode for each color has substantially the same area. Each of the unit pixels 127 is divided into the rectangular regions including the sub-pixel electrodes for display of a plurality of colors, and is formed by the sub-pixel electrodes. The number of sub-pixel electrodes is changed for each color. As a result, the effective aperture area is made different for each color. Here, it is preferred that the difference in the effective aperture area between colors is suitably set on the basis of the difference in the luminosity factor (brightness) and/or the color purity (saturation) between colors, and according to the required characteristics of the panel. Usually, the effective aperture area is made different between a color having a comparatively high luminosity factor and a color having a comparatively low luminosity factor. That is, the effective aperture area for a color having a comparatively high luminosity factor is made small, and the effective aperture area for a color having a comparatively low luminosity factor is made large. Specifically, when the broken-dotted line for equally dividing the unit pixel 127 shown in FIG. 8 in the lateral direction is taken as a boundary, and when the unit pixel 127 is divided into the rectangular region consisting of the pixel region of red (R) and the pixel region of green (G), and the rectangular region consisting of the pixel region of blue (B) and the pixel region of yellow (Y), the rectangular region on the upper side in FIG. 8 is formed so as to include two sub-pixels (R and G), and the rectangular region on the lower side in FIG. 8 is formed so as to include two sub-pixels (B and Y). In the sub-pixels 119R, 119G, 119B and 119Y, the length a of the side (the side in the longitudinal direction in FIG. 9) in parallel with the short side of the rectangular region is substantially the same, and the lengths b1 and b2 of the sides (the sides in the lateral direction in FIG. 9) in parallel with the long side of the rectangular region are different between R, B and G, Y.

Each of the pixel of red (R) and the pixel of blue (B) is formed such that three sub-pixel electrodes are arranged to form a right angle, and such that two sub-pixel electrodes are arranged side by side in the direction in parallel with the long side of the rectangular region, while each of the pixel of green (G), and the pixel of yellow (Y) is formed such that two sub-pixel electrodes are arranged in the direction in parallel with the short side of the rectangular region, and such that only one sub-pixel electrode is arranged in the direction in parallel with the long side of the rectangular region. In FIG. 9, the length b1 of the side of each of the pixel of red (R) and the pixel of blue (B), which side is in parallel with the long side of the rectangular region, is substantially twice the length b2 of the side of each of the pixel of green (G), and the pixel of yellow (Y), which side is in parallel with the long side of the rectangular region. When the non-transmissive portion in the pixel is taken into consideration, the practical aperture area ratio of the present embodiment is obtained as RB:GY=1.5:1.

The opposed substrate is configured such that a red (R) CF layer, a green (G) CF layer, a blue (B) CF layer, and a yellow (Y) CF layer are arranged on the main surface of a glass substrate respectively in correspondence with the pixel regions, and a light shielding portion (BM), which is referred to as a black matrix, is provided to partition the respective CF layers. Further, in FIG. 8 and FIG. 9, a BM is also arranged in the rectangular region in which the sub-pixel electrode is not provided (and which is located on the central lower side in the upper and lower rectangular regions). Further, as shown in FIG. 9, under the BM, not only the TFTs 125G and 125Y of the sub-pixel (G or Y) having the BM but also the TFT 125B and 125R of the sub-pixels (B or R on the right side of Y) adjacent to the sub-pixel having the BM are arranged. Further, a photo spacer 128 is also arranged under the BM.

Embodiment 2-1 is a form in which, under the BM, not only the TFT of the sub-pixel having the BM but also the TFT of the sub-pixel adjacent to the sub-pixel having the BM are arranged.

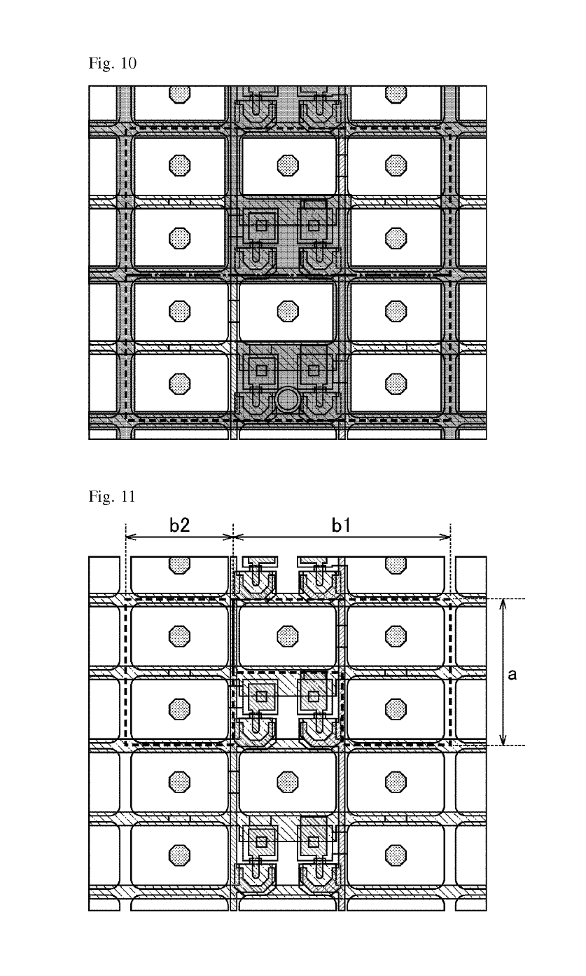

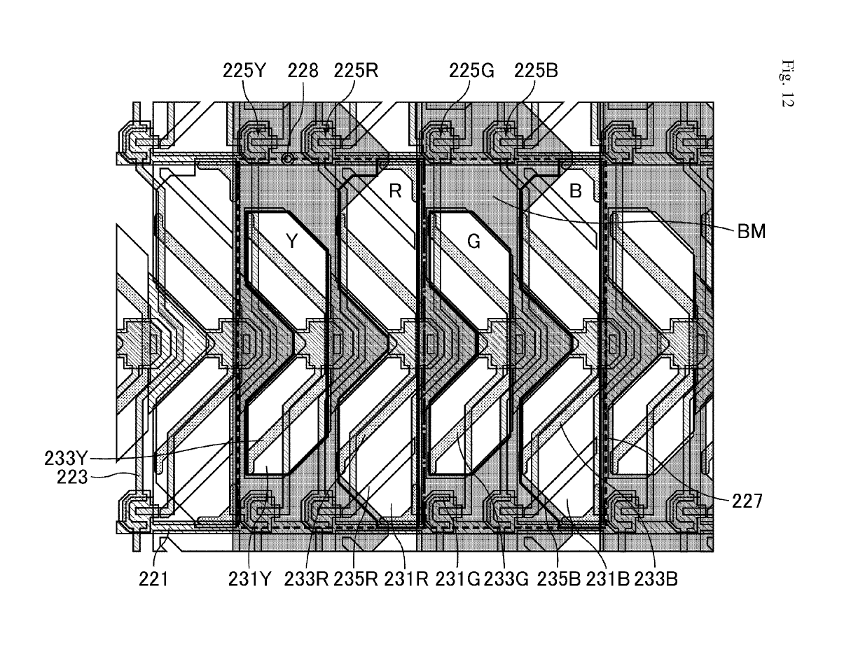

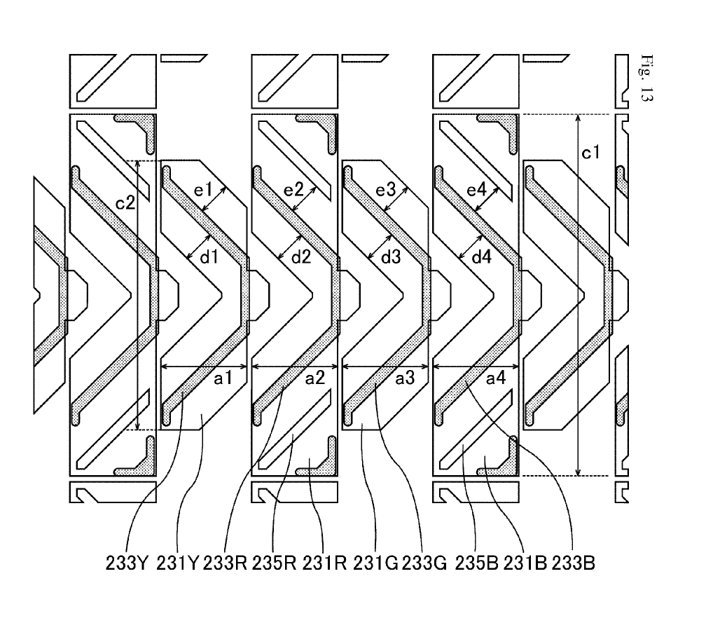

FIG. 10 is a schematic plan view showing a liquid crystal display panel of Embodiment 2-2. FIG. 11 is a view in which the black matrix is omitted in FIG. 10. Embodiment 2-2 is a form in which, in Embodiment 2-1, the contact hole, the CS (storage) capacitance of the sub-pixel having the BM, and the contact hole, the CS (storage) capacitance of the other sub-pixel adjacent to the sub-pixel having the BM are additionally arranged under the BM.

The other configuration (entire configuration) of each of Embodiment 2-1 and Embodiment 2-2 is similar to the other configuration (entire configuration) of each of Embodiment 1-1 and Embodiment 1-2.

The effects of Embodiment 2 are described on the basis of the results estimated when the size of one pixel set to 180 μm.

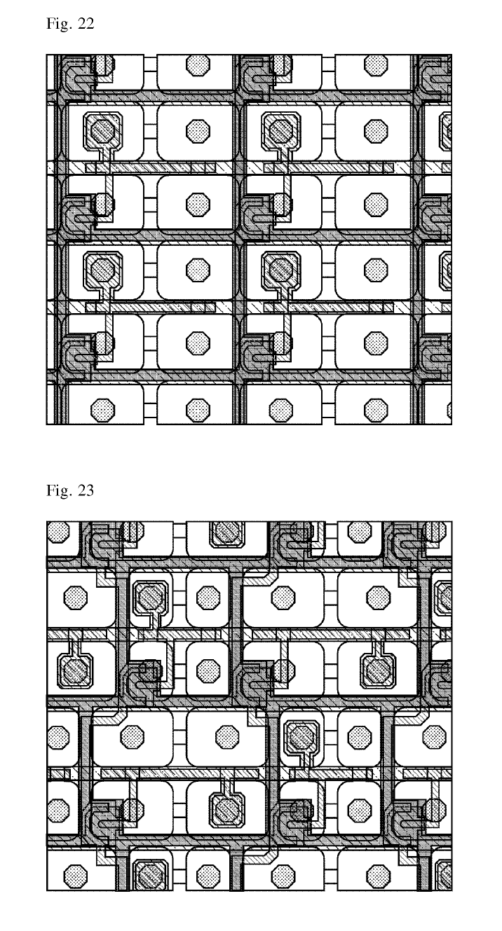

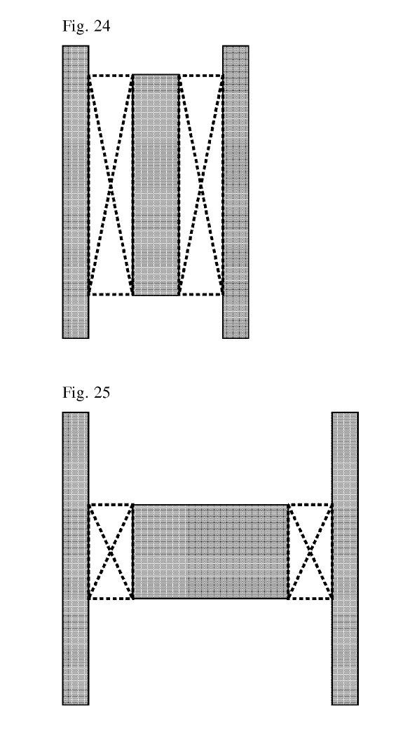

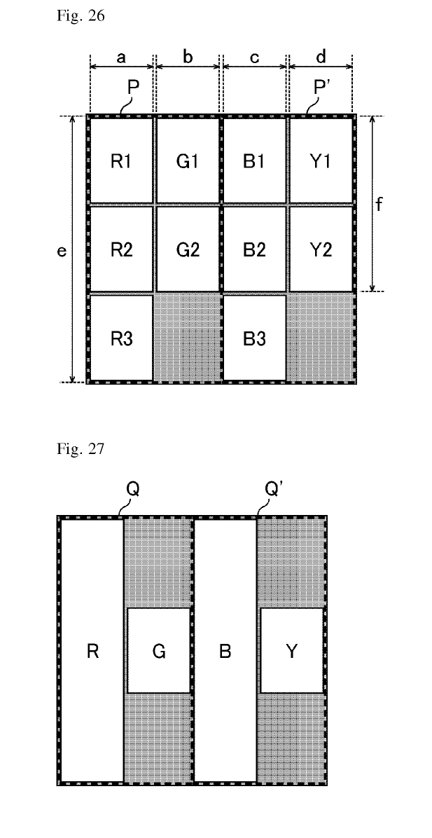

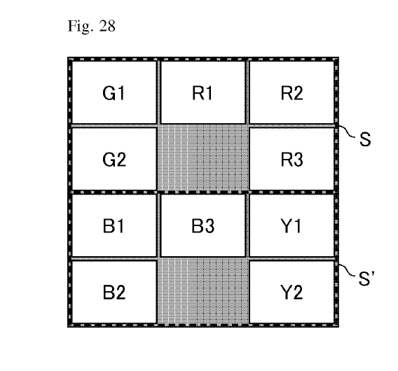

In the conventional art, when a panel using three colors of RGB is made to correspond to four colors of RGBY, especially in a high-definition panel, it is effective to form the sub-pixel in a square picture element (square sub-pixel) as shown in FIG. 22 from the viewpoint of securing the aperture ratio. When the display panel using three colors of RGB is simply made to correspond to four colors of RGBY, the CF transmissivity is improved, but the aperture ratio is reduced in the display using four primary colors. Therefore, the transmissivity is improved by 26%, but there arises a problem that the luminance of monochromatic color and complementary color is reduced (the luminance reduction rate of monochromatic color is about 10% (RGB ratio), but since white luminance is improved, it is visually recognized that the luminance of monochromatic color is more reduced).

When the aperture area ratio is set as RB:GY=1.5:1 to improve the luminance of monochromatic color and complementary color (for example, as in FIG. 23), the transmissivity remains to be improved by 10%. Further, the size of the sub-pixel electrode (the length of the short side of the sub-pixel electrode) is significantly different between RB and GY (RB: 43 μm, GY: 33 μm), and hence there remains a problem that the response speed and visual characteristics are changed for each color.

### Embodiment 2-1

In Embodiment 2-1, the areas of the sub-pixel electrodes of all the colors are made substantially equal to each other. In this configuration, when a rectangular BM is arranged in the region in which the sub-pixel electrode is not arranged, and when a TFT of a sub-pixel adjacent to the sub-pixel having the BM is arranged under the BM, the transmissivity is improved by 5%. When Y is further added, the color reproduction range is expanded by 5%. In this way, both the color reproduction range and the transmissivity can be improved. The sizes of the sub-pixel electrodes of all the colors are made equal to each other, and hence the difference in the response speed and visual angle characteristics between the colors is not recognized.

### Embodiment 2-2

As in Embodiment 2-2, when, under the BM arranged in the region of the sub-pixel in which region the sub-pixel electrode is not arranged, the TFT of the other sub-pixel adjacent to the sub-pixel having the BM, and the contact hole and the CS capacitance of each of the sub-pixel having the BM and the other sub-pixel are arranged, the transmissivity can be improved by 24% or more as compared with the display panel using RGB. When Y is further added, the color reproduction range is expanded by 5%. In this way, both the color reproduction range and the transmissivity can be improved. The sizes of the sub-pixel electrodes of all the colors are made equal to each other, and hence the difference in the response speed and visual angle characteristics between the colors is not recognized.

### Embodiment 3

Embodiment 3 relates to a form in which sub-pixels are arranged in a stripe shape in a liquid crystal display panel of a MVA mode.

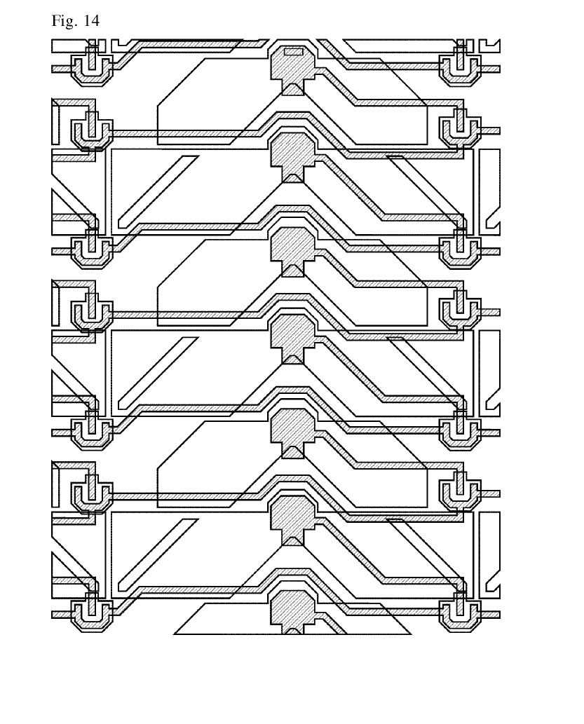

FIG. 12 is a schematic plan view showing a liquid crystal display panel of Embodiment 3. FIG. 13 is a view showing only alignment regulation means provided in the sub-pixel electrodes of the sub-pixels and the common electrode in FIG. 12. FIG. 14 is a view showing only the sub-pixel electrodes of the sub-pixels and the signal lines in FIG. 12.

Scanning lines 221 and signal lines 223 are arranged in a grid shape on the main surface of a glass substrate.

In each of a plurality of pixel regions in which the scanning lines 221 and the signal lines 223 are arranged, a sub-pixel electrode 231R is arranged in the pixel region of red (R), a sub-pixel electrode 231G is arranged in the pixel region of green (G), a sub-pixel electrode 231B is arranged in the pixel region of blue (B), and two sub-pixel electrodes 231Y are arranged in the pixel region of yellow (Y). A unit pixel 227 is formed by these four pixel regions. Each of the unit pixels 227 is divided into rectangular regions including sub-pixel electrodes respectively displaying a plurality of colors and is formed by these sub-pixel electrodes. The area of each of the sub-pixel electrodes is changed for each color. As a result, the area of the effective aperture portion is different for each color. Here, it is preferred that the difference in the effective aperture area between colors is suitably set on the basis of the difference in the luminosity factor (brightness) and/or the color purity (saturation) between colors, and according to the required characteristics of the panel. Usually, the effective aperture area is changed between a color having a comparatively high luminosity factor and a color having a comparatively low luminosity factor. That is, the effective aperture area of a color having a comparatively high luminosity factor is made small, and the effective aperture area of a color having a comparatively low luminosity factor is made large. Specifically, when the broken-dotted line for equally dividing the unit pixel 227 shown in FIG. 12 in the lateral direction is taken as a boundary, and when the unit pixel 227 is divided into the rectangular region consisting of the pixel region of yellow (Y) and the pixel region of red (R), and the rectangular region consisting of the pixel region of green (G) and the pixel region of blue (B), the rectangular region on the left side in FIG. 12 is formed so as to include two sub-pixels (Y and R), and the rectangular region on the right side in FIG. 12 is formed so as to include two sub-pixels (G and B). In the sub-pixels Y, R, G and B, the length a1 of the side (the side in the lateral direction in FIG. 13) in parallel with the short side of the rectangular region is substantially the same, and the lengths c1 and c2 of the sides (the sides in the longitudinal direction in FIG. 13), which are in parallel with the long side of the rectangular region and which respectively correspond to Y, G and R, B, are different from each other.

In FIG. 12, the length of the longitudinal side of the pixel of red (R) and the pixel of blue (B) is about 1.3 times the length of the longitudinal side of the pixel of green (G), and the pixel of yellow (Y).

When the non-transmissive portion in the pixel is taken into consideration, the practical aperture area ratio of the present embodiment is obtained as RB:GY=1.5:1.

Further, in the display panel in Embodiment 3, each of the plurality of sub-pixels RGBY has a (substantially) rectangular shape or has a substantially elliptical shape. Especially, in the display panel, the pixel is formed in such a manner that the long sides of the rectangular sub-pixels RGBY are arranged side by side substantially in the same direction, and that the rectangular sub-pixels RGBY are arranged adjacent to each other on both sides of the mutually adjacent long sides of the rectangular sub-pixels. In the sub-pixels RGBY, the length a1 of the short side of the rectangular shape is substantially the same, and the lengths c1 and c2 of the long sides of the rectangular shapes, which are respectively correspond to R, B and G, Y, are different from each other.

The opposed substrate is configured such that a red (R) CF layer, a green (G) CF layer, a blue (B) CF layer, and a yellow (Y) CF layer are arranged on the main surface of a glass substrate respectively in correspondence with the pixel regions, and a light shielding portion (BM), which is referred to as a black matrix, is provided to partition the respective CF layers. Further, the BM is also arranged in the region which is located on the upper and lower sides of the small sub-pixel in FIG. 1 and FIG. 2 and in which the sub-pixel electrode is not provided. Further, as shown in FIG. 12, not only the TFTs 225G and 225Y of the sub-pixel (G or Y) having the BM but also the TFTs 225B and 225R of the sub-pixel (B or R) adjacent to the sub-pixel (G) having the BM can be arranged under the BM. Further, a photo spacer 228 is also arranged under the BM.

Further, ribs 233Y, 233R, 233G and 233B which are alignment regulation means are formed on the opposed substrate.

In the display panel, each of the plurality of sub-pixels YRGB are formed by each of the sub-pixel electrodes 231Y, 231R, 231G and 231B respectively provided with the ribs 233Y, 233R, 233G and 233B. In the plan view of the pixel in the display panel, the distances d1, d2, d3, d4 between each of the ribs 233Y, 233R, 233G, 233B and each of the edges of the sub-pixel electrodes 231Y, 231R, 231G, 231B, and the distances e1, e3 between each of the ribs 233Y, 233G and each of the edges of the sub-pixel electrodes 231Y, 231G, and distances e2, e4 between each of the ribs 233R, 233B, and each of slits 235R, 235B are all substantially the same.

In Embodiment 3, when, under the BM that is arranged in the region in which the sub-pixel electrode is not arranged, the TFT of the sub-pixel having the BM and the TFT of the sub-pixel adjacent to the sub-pixel having the BM are arranged, the transmissivity can be improved by 7% or more as compared with the display panel using RGB. When Y is further added, the color reproduction range is expanded by 5%. In this way, both the color reproduction range and the transmissivity can be improved. The sizes of the sub-pixel electrodes of all the colors are made equal to each other, and hence the difference in the response speed and visual angle characteristics between the colors is not recognized.

### Embodiment 4

Embodiment 4 relates to an MVA mode liquid crystal display panel in which sub-pixels are arranged in a two-by-two matrix shape.

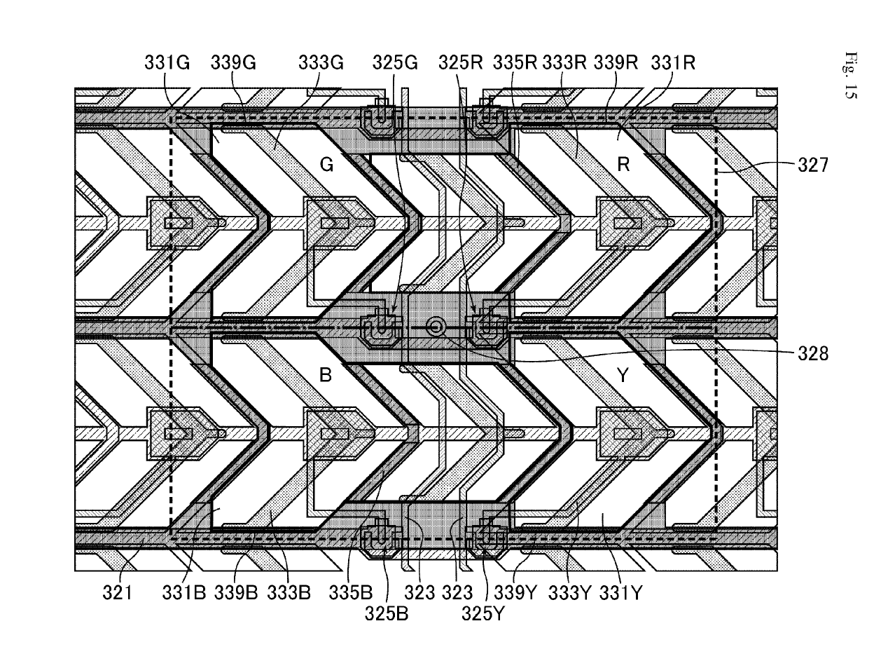

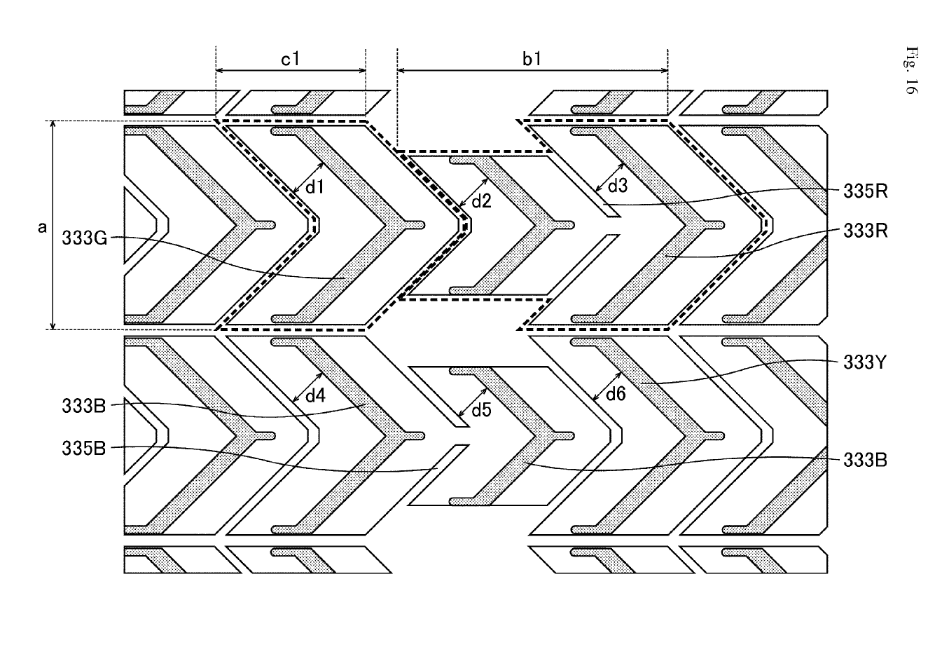

FIG. 15 is a schematic plan view showing a liquid crystal display panel of Embodiment 4. FIG. 16 is a view showing only alignment regulation means provided in the sub-pixel electrodes of the sub-pixels and the common electrodes in FIG. 15. FIG. 17 is a view showing only the sub-pixel electrodes of the sub-pixels and the signal lines in FIG. 15.

Scanning lines 321 and signal lines 323 are arranged in a grid shape on the main surface of a glass substrate.

In each of a plurality of pixel regions in which the scanning line 321 and the signal line 323 are arranged, a sub-pixel electrodes 331R is arranged in a pixel region of red (R), a sub-pixel electrode 331G is arranged in a pixel region of green (G), a sub-pixel electrode 331B is arranged in a pixel region of blue (B), and a sub-pixel electrodes 331Y is arranged in a pixel region of yellow (Y). A unit pixel is formed by these four pixel regions. A region 327 including the unit pixels is divided into the rectangular regions including the sub-pixel electrodes for display of a plurality of colors, and is formed by the sub-pixel electrodes. The area of sub-pixel electrodes is changed for each color. As a result, the areas of effective aperture portions 339R, 339G, 339B and 339Y are made different for each color. Here, it is preferred that the difference in the effective aperture area between colors is suitably set on the basis of the difference in the luminosity factor (brightness) and/or the color purity (saturation) between colors, and according to the required characteristics of the panel. Usually, the effective aperture area is changed between a color having a comparatively high luminosity factor and a color having a comparatively low luminosity factor. That is, the effective aperture area of a color having a comparatively high luminosity factor is made small, and the effective aperture area of a color having a comparatively low luminosity factor is made large. Specifically, when the broken-dotted line for equally dividing the unit pixel 327 shown in FIG. 15 in the lateral direction is taken as a boundary, and when the unit pixel 327 is divided into the rectangular region consisting of the pixel region of green (G) and the pixel region of red (R), and the rectangular region consisting of the pixel region of blue (B) and the pixel region of yellow (Y), the rectangular region on the upper side in FIG. 15 is formed so as to include two sub-pixels (G and R), and the rectangular region on the lower side in FIG. 15 is formed so as to include two sub-pixels (B and Y). In the sub-pixels G, R, B and Y, the length a of the side (the side in the longitudinal direction in FIG. 16) in parallel with the short side of the rectangular region is substantially the same, and the lengths b1 and c1 of the sides (the sides in the lateral direction in FIG. 16), which are in parallel with the long side of the rectangular region and which respectively correspond to Y, G and R, B, are different from each other.

In FIG. 16, the lateral length b1 of the sub-pixel of each of the pixel of red (R) and the pixel of blue (B) is substantially twice the lateral length c1 of the sub-pixel of each of the pixel of green (G) and the pixel of yellow (Y). When the non-transmissive portion in the pixel is taken into consideration, the practical aperture area ratio of the present embodiment is obtained as RB:GY=1.5:1.

Further, in the display panel of Embodiment 4, each of the plurality of sub-pixels RGBY has a polygonal shape.

The opposed substrate is configured such that a red (R) CF layer, a green (G) CF layer, a blue (B) CF layer, and a yellow (Y) CF layer are arranged on the main surface of a glass substrate respectively in correspondence with the pixel regions, and a light shielding portion (BM), which is referred to as a black matrix, is provided to partition the respective CF layers. Further, in FIG. 15, the BM is also arranged in the region in which the sub-pixel electrode is not provided (portions 339G and 339Y surrounded by thick solid lines represent BM aperture portions of sub-pixels having a small area, and portions 339R and 339B surrounded by thick solid lines represent BM aperture portions of sub-pixels having a large area). Further, as shown in FIG. 15, TFTs 325G, 325R, 325B and 325Y of the sub-pixels (G, R, B, Y) can be arranged under the BMs. Further, a photo spacer 328 is also arranged under the BM.

Further, ribs 333Y, 333R, 333G and 333B which are alignment regulation means are formed on the opposed substrate.

In the display panel, each of the plurality of sub-pixels YRGB are formed by the sub-pixel electrodes 331Y, 331R, 331G and 331B respectively provided with the ribs 333Y, 333R, 333G and 333B. In the plan view of the pixel in the display panel, the distances d1, d2, d4, d6 between each of the ribs 333Y, 333R, 333G, 333B and each of the edges of the sub-pixel electrodes 331Y, 331R, 331G, 331B, and the distances d3, d5 between each of the ribs 333R, 333B and each of the slits 335R, 335B are all substantially the same.

In Embodiment 4, when, under the BM in which the sub-pixel electrode is not arranged, the TFT of the sub-pixel having the BM and the TFT of the sub-pixel adjacent to the sub-pixel having the BM are arranged, the transmissivity can be improved by 26% or more as compared with the display panel using RGB. When Y is further added, the color reproduction range is expanded by 5%. In this way, both the color reproduction range and the transmissivity can be improved. The sizes of the sub-pixel electrodes of all the colors are made equal to each other, and hence the difference in the response speed and visual angle characteristics between the colors is not recognized.

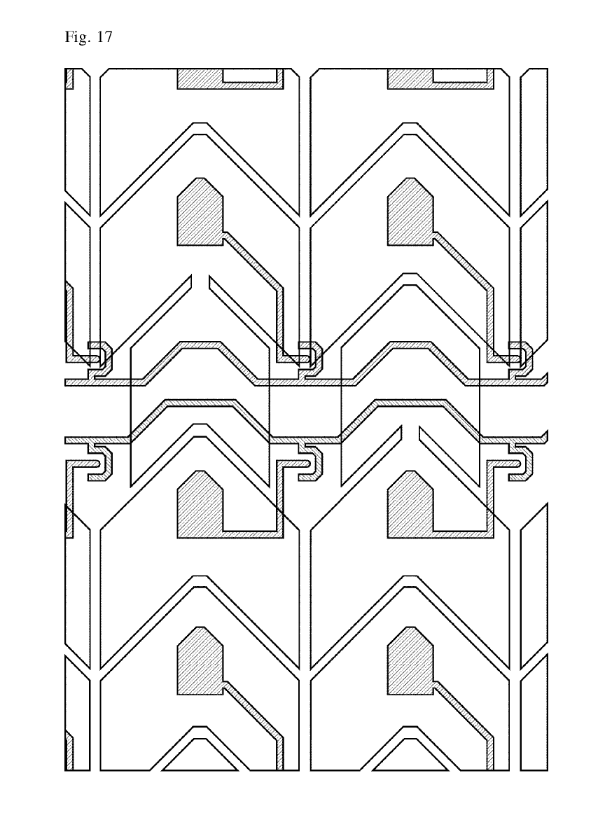

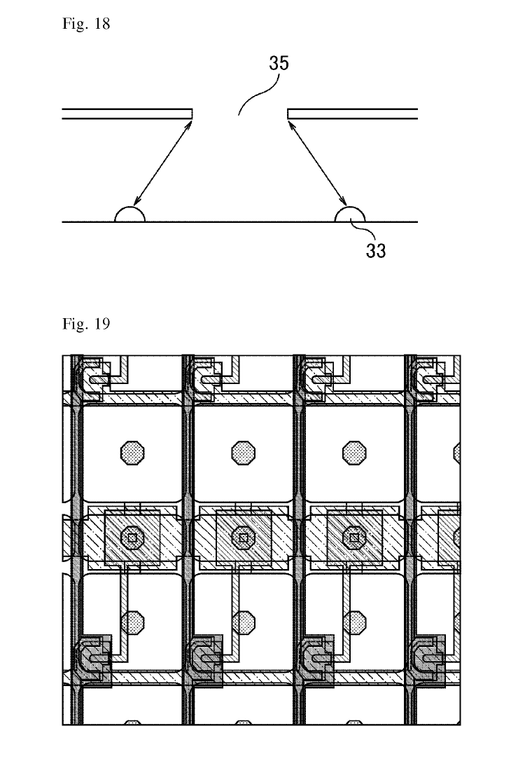

FIG. 18 is a schematic cross-sectional view showing a liquid crystal display panel of Embodiments 3 and 4. Here, the rib of Embodiments 3 and 4 is denoted by reference numeral 33, and the slit (electrode cut-out portion) of Embodiments 3 and 4 is denoted by reference numeral 35.

In the plan view of the pixel in the display panel, when the distance between the rib 33 and the slit (cutout portion) 35 is made substantially the same, the practical distance between the rib and the slit can be made substantially the same.

The aforementioned modes of respective embodiments may be employed in appropriate combination as long as the combination is not beyond the spirit of the present invention.

The present application claims priority to Patent Application No. 2010-146825 filed in Japan on Jun. 28, 2010 under the Paris Convention and provisions of national law in a designated State, the entire contents of which are hereby incorporated by reference.

### REFERENCE SIGNS LIST

11R, 11G, 11B, 11Y, 111R, 111G, 111B, 111Y, 211R, 211G, 211B, 211Y, 311R, 311G, 311B, 311Y, 231R, 231G, 231B, 231Y, 331R, 331G, 331B, 331Y: Sub-pixel electrode
13R, 13G, 13B, 13Y, 113R, 113G, 113B, 113Y, 213R, 213G, 213B, 213Y, 313R, 313G, 313B, 313Y: Alignment regulation means
15R, 15G, 15B, 15Y: CS (Storage) capacitance
17R, 17G, 17B, 17Y: Contact hole
19, 119: CS (storage capacitance) wiring
21, 121, 221: Scanning line
23, 123, 223: Signal line
25R, 25G, 25B, 25Y, 125R, 125G, 125B, 125Y, 225R, 225G,
225B, 225Y: TFT
27, 127, 227, 327: Unit pixel
29a, 29b: Sub-pixel
33, 233Y, 233R, 233G, 233B, 333Y, 333R, 333G, 333B: Rib
35, 235R, 235B, 335R, 335B: Slit
BM: Black matrix

1. A display panel in which one pixel is formed by a plurality of sub-pixels, wherein:
when a region including one pixel is divided into a plurality of rectangular regions, at least one of the rectangular regions includes two or more sub-pixels; and
in each of the sub-pixels, the length of the side in parallel with the short side of the rectangular region is substantially the same, and in at least one of the sub-pixels, the length of the side in parallel with the long side of the rectangular region is different.

2. The display panel according to claim 1, wherein:
in the display panel, each of the plurality of sub-pixels has a rectangular shape, and the long sides of the rectangular shapes are arranged side by side in the same direction; and
in the sub-pixels, the lengths of the short sides of the rectangular shapes are substantially the same as each other, and in at least one of the sub-pixels, the length of the long side of the rectangular shape is different.

3. The display panel according to claim 1, wherein:
in the display panel, each of the plurality of sub-pixels is formed by a sub-pixel electrode having alignment regulation means, and at least one of the sub-pixels includes two or more sub-pixel electrodes; and
in plan view of the pixel in the display panel, the distance between the alignment regulation means and the edge of the sub-pixel electrode is substantially the same for the sub-pixel electrodes in two or more sub-pixels in the same pixel.

4. The display panel according to claim 1, wherein:
in the display panel, each of the plurality of sub-pixels is formed by a sub-pixel electrode having two or more kinds of alignment regulation means; and
in plan view of the pixel in the display panel, the distance between one kind of the alignment regulation means and the other kind of the alignment regulation means is substantially the same for sub-pixel electrodes in two or more sub-pixels in the same pixel.

5. The display panel according claim 1, wherein: in plan view of the main surface of the panel, the pixel includes a rectangular light shielding region in a region that is included in the display region and is other than the region in which the sub-pixel is arranged.

6. The display panel according to claim 5, wherein a thin-film transistor is arranged in the light shielding region.

7. The display panel according to claim 5, wherein a columnar spacer is arranged in the light shielding region.

8. The display panel according to claim 5, wherein a sub-pixel electrode and/or a storage capacitance wiring are/is arranged in the light shielding region.

9. The display panel according to claim 1, wherein in the display panel, the polarity of the potential of the sub-pixel electrode for display of each color is reversed at every natural number multiple of the number of sub-pixels included in one pixel in the same row direction.

10. The display panel according to claim 1, wherein:
one of the pair of substrates includes scanning lines, signal lines, storage capacitance wirings, a thin-film transistor connected to each of the scanning lines and each of the signal lines, and a sub-pixel electrode connected to the thin-film transistor;
the other of the pair of substrates includes a common electrode;
the sub-pixel electrode is arranged in correspondence with one sub-pixel; and
at least one of the size of the switching element and the value of the storage capacitance of the sub-pixel having the large area is larger than at least one of the size of the switching element and the value of the storage capacitance of the sub-pixel having the small area.

11. The display panel according to claim 1, wherein: the display panel is a liquid crystal display panel using a liquid crystal layer as a display element.

12. A display device comprising the display panel according to claim 1.
